(19) United States
(12) Patent Application Publication
(10) Pub. No.: US 2014/0145386 A1
(43) Pub. Date: May 29, 2014

(54) INSTALLATION TOOL

(71) Applicant: HON HAI PRECISION INDUSTRY CO., LTD., New Taipei (TW)

(72) Inventors: CHEN-LU FAN, New Taipei (TW); LI-PING CHEN, New Taipei (TW)

(21) Appl. No.: 13/931,567

(22) Filed: Jun. 28, 2013

(30) Foreign Application Priority Data
Nov. 26, 2012 (TW) 101144239

(51) Int. Cl. H05K 7/14

(52) U.S. Cl. CPC H05K 7/14
USPC 269/40

(57) ABSTRACT

An installation tool, for installing four supports in a server rack, includes two first positioning plates and two second positioning plates secured to the two first positioning plates. The four supports form a rectangle frame for stacking a number of servers. The installation tool is secured in the rectangle frame and maintains the four supports when the four supports are screwed to holding plates of the server rack to prevent the rectangle frame from being deformed, and then the installation tool is removed from the server rack reused in another server rack.

### BACKGROUND

1. Technical Field

The present disclosure relates to installation tools, and particularly to an installation tool for installing supports in a server rack.

2. Description of Related Art

A server rack includes four supports, which form a rectangle frame for stacking a number of servers. Generally, the four supports are secured to a number of holding plates with a number of screws. However, when the four supports are screwed to the holding plates, relative positions of the four supports are easy changed, causing local deformation to the rectangular frame, which may cause squeezing when the severs are positioned in the rectangular frame. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an installation tool and a server rack.

FIG. 2 is an assembled, isometric view of the installation tool and four supports of FIG. 1.

FIG. 3 is an assembled, isometric view of the installation tool and the server rack of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

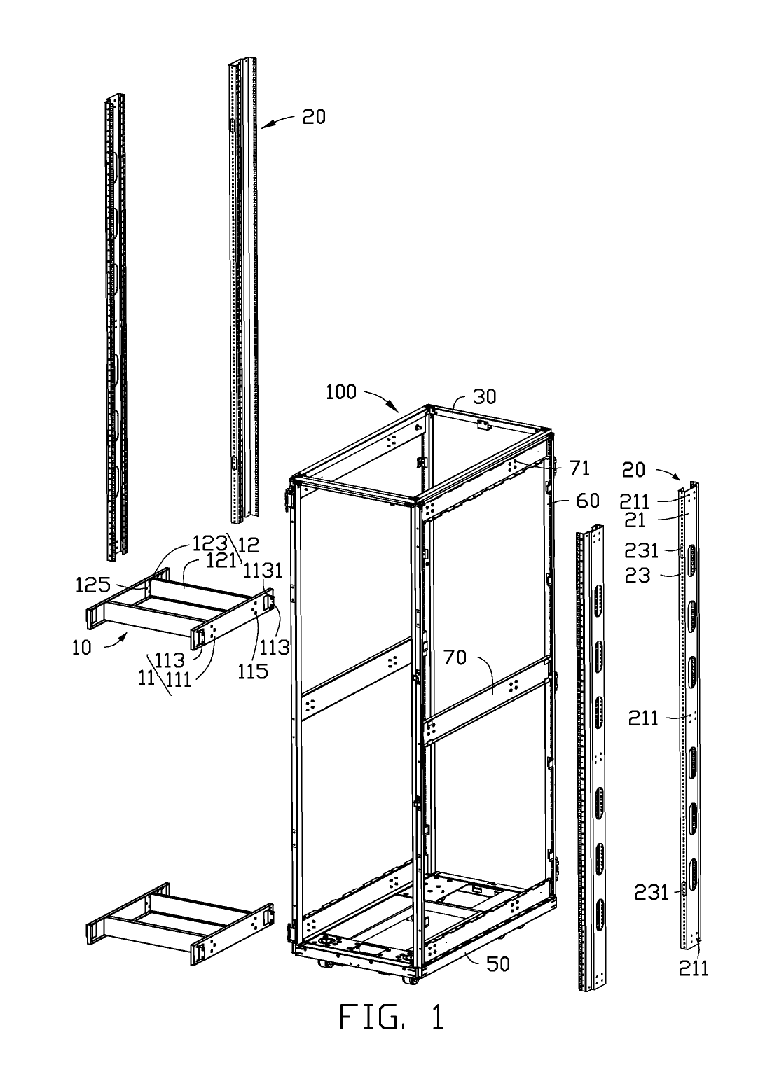

FIG. 1 shows two installation tools 10 and a server rack 100 in accordance with an embodiment. The two installation tools 10 are used for securing four supports 20 to the server rack 100.

Each installation tool 10 includes two first positioning plates 11 and two second positioning plates 12. Each first positioning plate 11 includes a first plate body 111 and two installation pieces 113 extending from an outer surface of the first plate body 111. The first plate body 111 defines two sets of first mounting holes 115. Each set of first mounting holes 115 includes three first mounting holes 115. The three first mounting holes 115 are connected to form a triangle. Each installation piece 113 defines two first installation holes 1131. Each second positioning plate 12 includes a second plate body 121 and two locking pieces 123, extending from opposite side edges of the second plate body 121. Each locking piece 123 defines three second mounting holes 125 corresponding to the set of first mounting holes 115. In one embodiment, each installation piece 113 is substantially perpendicular to the first plate body 111, each locking piece 123 is substantially perpendicular to the second plate body 121, and the two first plate bodies 111 are substantially parallel to each other.

The two second positioning plates 12 are secured between the two first positioning plates 11. The two second plate bodies 121 are substantially parallel to each other, and are substantially perpendicular to each first plate body 111. The locking piece 123 abuts an inner surface of the first plate body 111. Each first mounting hole 115 is aligned with one of the three second mounting holes 125. A plurality of screws (not shown) are secured to the first mounting holes 115 and the second mounting holes 125 to secure the first positioning plate 11 to the second positioning plate 12. A length of the first plate body 111 is greater than a length of the second plate body 121.

The server rack 100 includes a top frame 30, a bottom frame 50, four braces 60, and a plurality of holding plates 70. The four braces 60 are secured to four corners of the top frame 30 and the bottom frame 50. Each holding plate 70 is secured between two adjacent braces 60. The plurality of holding plates 70 are arranged two rows, which are substantially parallel to each other. Each holding plate 70 defines two sets of first locking holes 71. Each set of first locking holes 71 are connected together to form a rectangle.

Each support 20 includes a main plate 21, an installation plate 23 perpendicularly connected to the main plate 21, and a flange 25 extending from an edge of the installation plate 23. The flange 25 is substantially perpendicular to the installation plate 23 and parallel to the main plate 21. The main plate 21 defines three sets of second locking holes 211. Each set of second locking holes 211 are connected together to form a rectangle. Each second locking hole 211 corresponds to one of the first locking holes 71. The installation plate 23 defines two sets of second installation holes 231. Each second installation holes 231 corresponds to one of the first installation holes 1131.

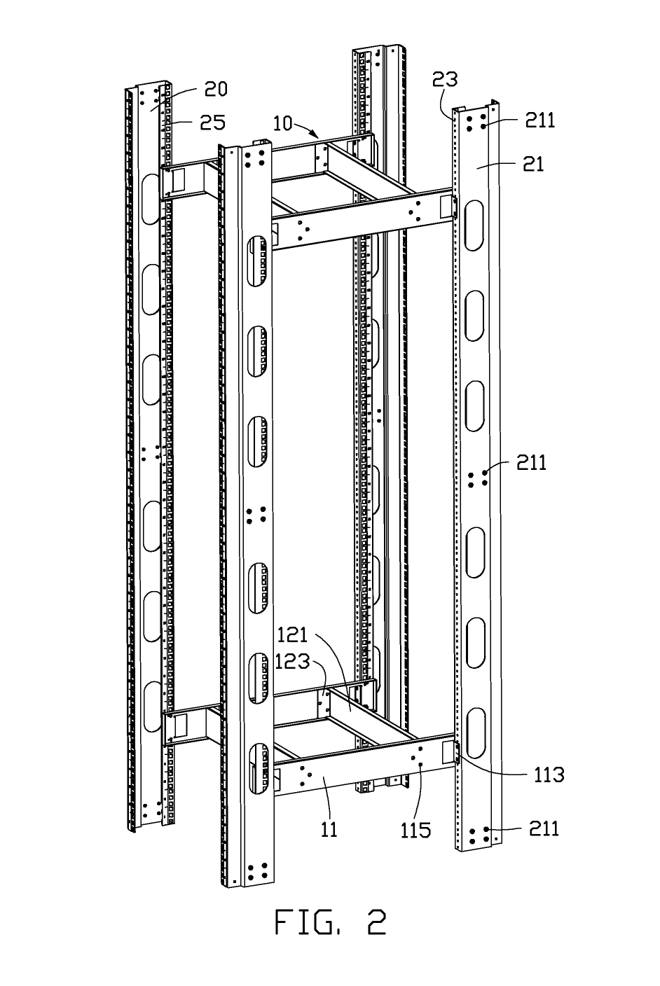

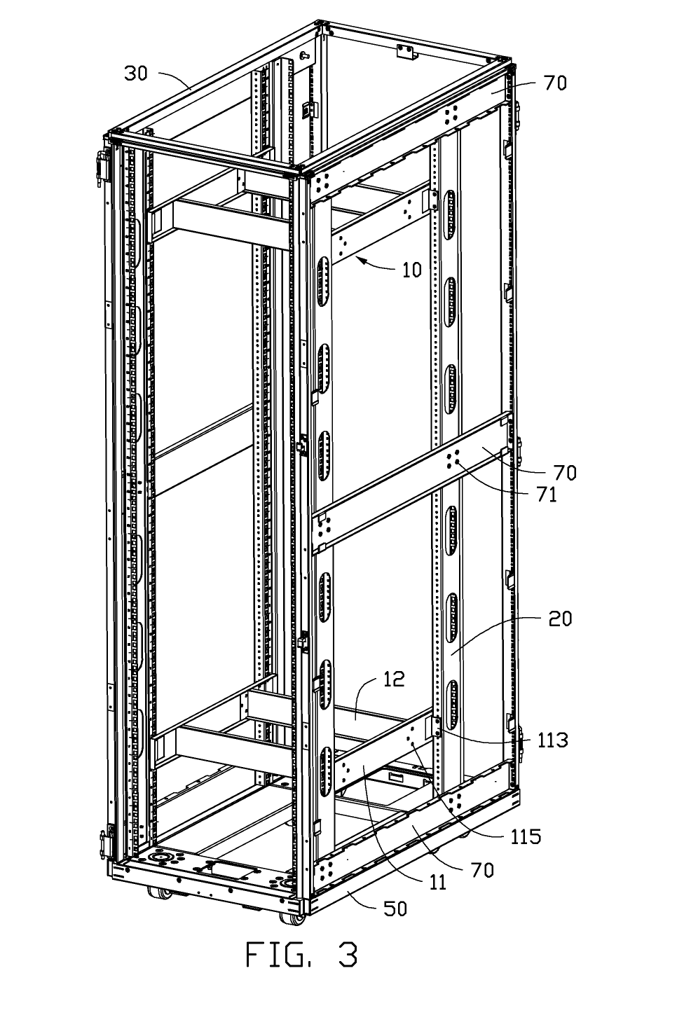

FIG. 2 and FIG. 3 show that, in assembly of each support 20 to the server rack 100, each support 20 is placed in the server rack 100, and each second locking hole 211 is aligned with one of the first locking holes 71.

The two installation tools 10 are placed in the server rack 100, and each first positioning plate 11 abuts the flange 25. Each installation piece 113 abuts one installation plate 23, and each first installation hole 1131 is aligned with one of the second installation holes 231. The two installation tools 10 are secured to the four supports 20 by a plurality of screws inserting into the first installation hole 1131 and the second installation hole 231. One of the two installation tools 10 is located in an upper portion of the four supports 20. The two installation tools 10 are located in opposite ends of the four supports 20. Another plurality the screws are screwed into the first locking hole 71 and the second locking hole 211, to secure the four supports 20 to the holding plate 70. When the four supports 20 are screwed to the holding plate 70, the installation tools 10 prevent the four supports 20 from moving relative each other.

The plurality of screws secured to each installation tool 10 and the supports 20 are removed, allowing the two installation tools 10 to be removed from the server rack 100 and reused in another server rack.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An installation tool, for installing four supports in a server rack, comprising:
two first positioning plates, and each first positioning plate comprising a first plate body; and
two second positioning plates secured to the two first positioning plates, and each second positioning plate comprising a second plate body;
wherein the two first plate bodies are substantially parallel to each other, the two second plate bodies are substantially parallel to each other, and the first plate body is substantially perpendicular to the second plate body; the installation tool is configured for being mounted in a rectangular frame formed by the four supports and maintains the four supports when the four supports are installed in the server rack; and the installation tool is configured for being removed from the rectangular frame after the four supports are installed in the server rack.

2. The installation tool of claim 1, wherein the two second plate bodies are secured between the two first plate bodies.

3. The installation tool of claim 1, wherein a length of the first plate body is greater than a distance between the two second positioning plates.

4. The installation tool of claim 1, wherein each first positioning plate of the two first positioning plates further comprises two installation pieces extending from the first plate body, each installation piece is substantially perpendicular to the first plate body and configured for being secured to one of the four supports.

5. The installation tool of claim 4, wherein the first plate body defines a set of first mounting holes; the second plate body further comprises a locking piece extending from the second plate body, and the locking piece defines a set of second mounting holes aligned with the set of first mounting holes.

6. The installation tool of claim 5, wherein the set of first mounting holes are connected together to form a triangle.

7. The installation tool of claim 5, wherein each installation piece extends from an outer surface of the first plate body, and the locking piece abuts against an inner surface of the first plate body.

8. The installation tool of claim 5, wherein the locking piece is substantially perpendicular to the second plate body.

9. The installation tool of claim 5, wherein the locking piece is secured to the second plate body.

10. An installation tool, for installing four supports in a server rack, comprising:
two first positioning plates, and each first positioning plate comprising a first plate body and two installation pieces extending from the first plate body; and
two second positioning plates secured to the two first positioning plates, and each second positioning plate comprising a second plate body;
wherein the two first plate bodies are substantially parallel to each other, the two second plate bodies are substantially parallel to each other, and the first plate body is substantially perpendicular to the second plate body; the first plate body is configured for abutting against main plates of two of the four supports, and each installation piece is substantially perpendicular to the first plate body and configured for being secured to a flange of one of the four supports extending from the main plates.

11. The installation tool of claim 10, wherein the two second plate bodies are secured between the two first plate bodies.

12. The installation tool of claim 10, wherein a length of the first plate body is greater than a distance between the two second positioning plates of the two second positioning plates.

13. The installation tool of claim 10, wherein the first plate body defines a set of first mounting holes; the second plate body further comprises a locking piece extending from the second plate body, and the locking piece defines a set of second mounting holes aligned with the set of first mounting holes.

14. The installation tool of claim 13, wherein the set of first mounting holes are connected together to form a triangle.

15. The installation tool of claim 13, wherein each installation piece extends from an outer surface of the first plate body, and the locking piece abuts against an inner surface of the first plate body.

16. The installation tool of claim 13, wherein the locking piece is substantially perpendicular to the second plate body.

17. The installation tool of claim 13, wherein the locking piece is secured to the first plate body.
